(19) United States
(12) Patent Application Publication
(10) Pub. No.: US 2011/0156033 A1
(43) Pub. Date: Jun. 30, 2011

(54) METHOD AND SYSTEM FOR TRACING DIE AT UNIT LEVEL

(75) Inventors: Yohanes Bintang, Batam (ID); Enghsiung Ng, SG Abong (MY)

(73) Assignees: STMICROELECTRONICS ASIA PACIFIC PTE. LTD., SINGAPORE (SG); STMICROELECTRONICS SDN BHD, MUAR JOHORE (MY)

(21) Appl. No.: 12/651,389

(22) Filed: Dec. 31, 2009

(51) Int. Cl. H01L 23/544; H01L 21/56; H01L 21/50; H01L 21/66; G06F 17/30

(52) U.S. Cl. 257/48; 438/127; 438/123; 438/15; 707/705; 257/E21.502; 257/E21.499; 257/E21.521; 257/E23.179; 707/E17.001; 707/E17.044; 707/802

(57) ABSTRACT

A method and system for tracing die at unit level, comprising: assigning a first identification to a support member including a plurality of die support units; generating a second identification corresponding to a die support unit, the second identification including the first identification and a coordinate of the die support unit within the support member; correlating the second identification to a third identification of a die; attaching the die to the die support unit to generate a packaged die; and assigning the second identification to the packaged die.

### BACKGROUND

1. Technical Field

This invention relates generally to semiconductor and manufacturing methods thereof, and more particularly, but not exclusively, to tracking a unique identification to a dice after being singulated from a wafer and then marking this identification on the final package.

2. Description of the Related Art

A wafer undergoes many manufacturing processes to form many thousands of devices on it. During and after the manufacturing processes, the wafer is conventionally subjected to a series of testing procedures to confirm functionality of the devices, determine speed of operation, and assure quality and reliability. Data of the manufacturing processes and testing procedures are collected and stored in a database that identifies the wafer and each die on the wafer. Such data are stored in correlation with the wafer identification so that the process history and testing results of the devices on the wafer can be tracked as the wafer moves through the process line and toward packaging.

After the wafer is completed, a wafer probe test is carried out in which each die on the wafer is tested for functionality. The functional die may be tested for operational characteristics, called a bin sort, based on various properties, such as memory speed, CPU clock speed, and the like.

After dicing, the non-functional die are discarded and the functional die are sorted into the respective bins, with new identification numbers assigned based on their bin sort properties.

For some types of devices, only a functional test is performed and the die are sorted into two groups: functional and non-functional, and a bin sort is not carried out.

According to one prior art process, when a wafer is tested at a probe station after it is manufactured, the data is stored in a computer memory as a wafer map that identifies which die on the wafer are defective and which are operational. If the operational die are being sorted into bins, based on such features as memory speed, clock speed, or other factors, this information is also stored on the wafer map. When the wafer is diced at the back-end packaging, each die is assigned a new part number based on the bin sort that was determined. The wafer map is read to identify which dice are to be discarded and which are to be sorted into the different bins. Since the die are assigned new numbers based on the bins sort, the wafer map is no longer useful and tracking the die based on the wafer and lot is no longer carried out.

When the wafer are sawed into dice and packaged into individual units during the packaging process, sometimes called the back-end manufacturing process, the historical wafer information related to each singulated die cannot be tracked any more due to absence of linking between the front-end manufacturing process and the back-end packaging manufacturing process. If a packaged die is later determined as defective or unreliable, it would be desirable to know the full process history and testing results of the die to help track down the problem.

### BRIEF SUMMARY

In one embodiment, there is provided a method, comprising: assigning a first identification to a support member that include a plurality of die support units; generating a second identification corresponding to a die support unit, the second identification including the first identification and a coordinate of the die support unit within the support member; correlating the second identification to a third identification of a die; attaching the die to the die support unit to assemble a packaged die; and marking a tracking identification on the packaged die that links to the second identification.

In another embodiment, there is provided a system, comprising: a detector configured to detect a first recognizable pattern from a support member that is composed of a plurality of die support units; a processor comprising: a decoding unit configured to decode the first recognizable pattern into a first identification; a second identification generating unit coupled to receive the first identification of the support member from the decoding unit and configured to generate a second identification corresponding to a die support unit within the support member on the basis of the first identification wherein the second identification includes the first identification and the coordinate of the die support unit on the support member; a storing unit configured to store in a database the second identification in one-to-one correspondence to the third identification of the die that is attached to the die support unit and then packaged; and an encoding unit configured to encode the second identification into a second recognizable pattern; and a marking head configured to mark the second recognizable pattern on the packaged die.

In still another embodiment, there is provided a packaged die comprising: a die support unit separated from a support member that includes a plurality of die support units, the support member being marked with a first recognizable pattern encoded from a first identification; and a die attached to the die support unit and then packaged to be the packaged die, the die being separated from a wafer that includes a plurality of dice and having a third identification, wherein the packaged die is marked with a second recognizable pattern encoded from a second identification that includes the first identification and the coordinate of the die support unit, and the second identification is correlated with the third identification.

With the die tracing system and method, it is possible to trace a die at unit level.

Additional features of the disclosure will be described, hereinafter, which form the subject of the claims of the invention. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the invention as set forth in the appended claims.

### BRIEF DESCRIPTION OF THE SEVERAL VIEWS OF THE DRAWINGS

For a more complete understanding of the present disclosure, and the advantages thereof, reference is now made to the following descriptions taken in conjunction with the accompanying drawings, in which:

FIG. 1 is a schematic view of tracing die according to an embodiment;

FIG. 2 is a schematic view of tracing die according to an embodiment.

FIG. 3A illustrates a flow chart of a method of tracing die according to an embodiment;

FIG. 3B is an example flowchart of the step 101 according to the embodiment illustrated in FIG. 3B;

FIG. 4 illustrates a schematic view of a system 40 that can implement the steps 102-107 according to the embodiment illustrated in FIG. 1;

FIG. 5 illustrates an example flowchart of the step 102 according to the embodiment illustrated in FIG. 1;

FIG. 6 illustrates an example flowchart of the step 103 according to the embodiment illustrated in FIG. 1; and

FIG. 7 illustrates an example flowchart of step 105 according to the embodiment illustrated in FIG. 1.

FIG. 8 is a top side view of one embodiment of a support member according to the present invention.

FIG. 9 is the support member at a next stage in the process with the die attached.

FIG. 10 is a fully packaged die with the unique identification code thereon.

Corresponding numerals and symbols in different figures generally refer to corresponding parts unless otherwise indicated. The figures are drawn to clearly illustrate the relevant aspects of embodiments of the present disclosure and are not necessarily drawn to scale. To more clearly illustrate certain embodiments, a letter indicating variations of the same structure, material, or process step may follow a figure number.

### DETAILED DESCRIPTION

The making and using of embodiments are discussed in detail below. It should be appreciated, however, that specific embodiments discussed are merely illustrative, and do not limit the scope of the invention.

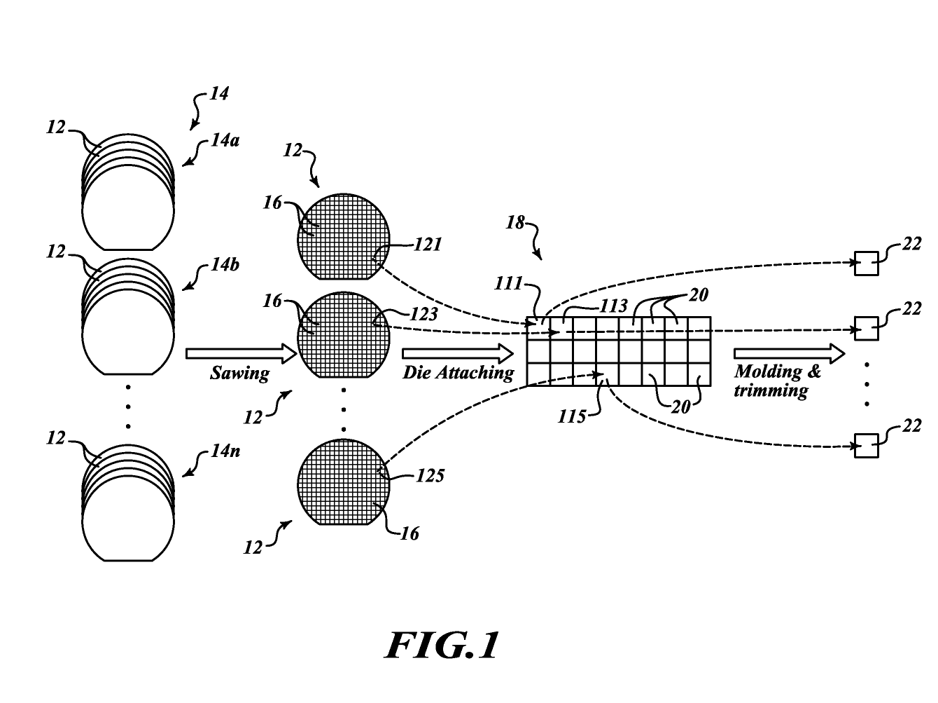

FIG. 1 illustrates schematically the process of manufacturing tested wafers into packaged dice where the wafers are sawed into dice 12 and then the dice 12 are picked and attached to a support member 11 and finally the support member 11 carrying the dice 12 is molded and trimmed into individual packaged dice 13.

FIG. 1 is a schematic view of tracing die according to an embodiment. FIG. 1 shows a plurality of wafers 12 grouped according to respective lots 14. A first lot is labeled 14a, a second lot 14b, and subsequent lots 14n. Within each lot 14 are a plurality of wafers. For example, in lot 14a there may be 25 wafers in some front end technologies. In other manufacturing front ends, the lot size may vary from a small of one wafer per lot to in the range 10 to 25 wafers per lot. As wafer 12 in each lot 14 travels through the semiconductor manufacturing line, various processes are carried out to form the integrated circuits thereon. At various stages during the manufacturing process, the wafers 12 are subjected to various tests for functionality and to determine specific process parameters. The results of these tests are stored in a wafer map for each wafer 12.

After the manufacturing process is complete, each wafer 12 is subjected to a wafer probe test in which each die 16 on the wafer is tested to determine its functionality and, if functional, various operating parameters.

Each wafer 12 contains a large number of individual die 16 therein. Depending on the wafer size and the die size, a wafer 12 may contain several dozen, several hundred, or, in some cases, several thousand individual die 16.

At the wafer probe testing of the individual die on each wafer, further data for the wafer map is generated and stored. According to one embodiment of the invention, the wafer map stores, for each wafer 12, the particular identity of the wafer, the lot number of the wafer, and a complete tracking of the full manufacturing process for that particular wafer, including the results of specific tests carried out during the manufacturing process. The wafer map also contains location information of each individual die 16 on each wafer 12, for example, the x and y coordinates of each die on the wafer.

The wafer 12, together with the stored wafer map, is transferred to a back-end processing location for dicing and packaging. In some situations, the back-end dicing and packaging operation are within the same company, while in other embodiments, the back-end processing is in a separate country and may be carried out by a completely separate company from the company which made the wafer 12. For example, companies such as IBM and STMicroelectronics have their own back-end packaging facilities at which their own wafers are tested, diced and packaged. In other instances, a wafer made by a company such as Freescale, Texas Instruments, or TSMC is sent to semiconductor packaging and assembly test specialty companies such as Amkor, Advanced Semiconductor Engineering, or STATS ChipPAC for dicing and packaging. In some cases, the wafer probe testing and generation of the wafer map are done by the specialty package company and not by the company that made the wafer 12.

After being diced into individual die 16, the die are placed on a support member 18. The support member 18 includes a plurality of die support units 20. The support member 18 may be any one of a number of acceptable package support members known in the art. In one embodiment, the support member 18 is the lead frame having a downset die pad and individual lead fingers, for each die support unit 20, as is known in the art. In other embodiments, the support member 18 is a printed circuit board for a ball grid array or a flip chip, while in other embodiments, it is a dielectric carrier plate to support the die while a molding compound is applied and it is later removed.

Lead frames are currently constructed with a large number of configurations including dual inline packages (DIPs); small outline integrated circuit packages (SOICPs); quad flat pack (QFPs), including standard quad flat packs and thin quad flat packs (TQFPs); thin shrink small outline packages (TSSOPs); power SOP packages; micro lead frame packages; and a number of other lead frame configurations.

Support members are also provided for chips packaged using ball grid arrays or LAN grid arrays. These include various types of packages, including PBGA, CABGA, CTBGA, SBGA, and a number of other configurations.

In addition, the support member 18 may be in the form of a flip chip substrate of a type well known in the art including such packages as a flip chip CSP, a flip chip ball grid array, and other configurations.

In other instances, the support member 18 may be a carrier onto which the die are adhered by a tape layer and subsequently encapsulated while mounted on the carrier. The packaged die may be later singulated after removal from the carrier, the die support units being constructed on the die while it rests on the carrier. In this case, parts of the support member 18 and die support unit do not become encapsulated with the die 16, as happens with a lead frame, but these still are the support members during the packaging process.

In each of these different types of packages, a support member 18 has a support substrate which may be a metal lead frame, a printed circuit board, an insulating laminate layer or another type of material which is organized having locations for a large number of die support units 20 thereon.

As shown in FIG. 1, after the die 16 are diced by sawing the wafers at the scribe lines, each individual die is placed at a die support unit 20 on the support member 18. After this, additional packaging steps are carried out on the die 16 in order to construct a final package having the die enclosed therein as explained herein. The package die is often referred to in the art as a chip or packaged integrated circuit. A single support member 18 may have anywhere from a few dozen to many hundreds of die support units 20 thereon. After each die 16 is properly packaged in each die support unit 20, the individual die support units 20 are singulated from each other and individual packaged die 22 are prepared for shipment to a customer for end use in electronic products such as a cell phone, a computer, iPhone, or the like.

Prior to shipment to a customer, the packaged computer chips 22 are marked with an identification of the die which is packaged therein. According to one embodiment of the present invention, the marking on the package contains information indicative of the particular wafer 12 on which the die 16 was made and also the exact location coordinates of that particular die in the wafer. In addition, the marking indication provides information regarding the identity of the wafer map created for that particular wafer during the manufacturing and testing process. The wafer map is stored by the manufacturer in a long-term storage location. In the event a customer has questions after the purchase of the product, even several years later, the marking which is placed on the package 22 provides sufficient indication that the particular lot of the wafer, the wafer number with in the lot, as well as the exact location of the specific die on the specific wafer can be determined and a match made to the wafer map that is stored for that particular die and that particular wafer. Such a wafer map will include the various testing that was carried out on that particular die through the entire manufacturing process and at the wafer probe test.

In order to achieve the matching of the packaged die 22 to a particular lot and a particular wafer within the lot and a particular location for the die on the wafer, an identification is provided during the packaging process so that the indication of this information can be known for each die 16 on each die support unit and correctly tracked during the backend packaging and marking assembly.

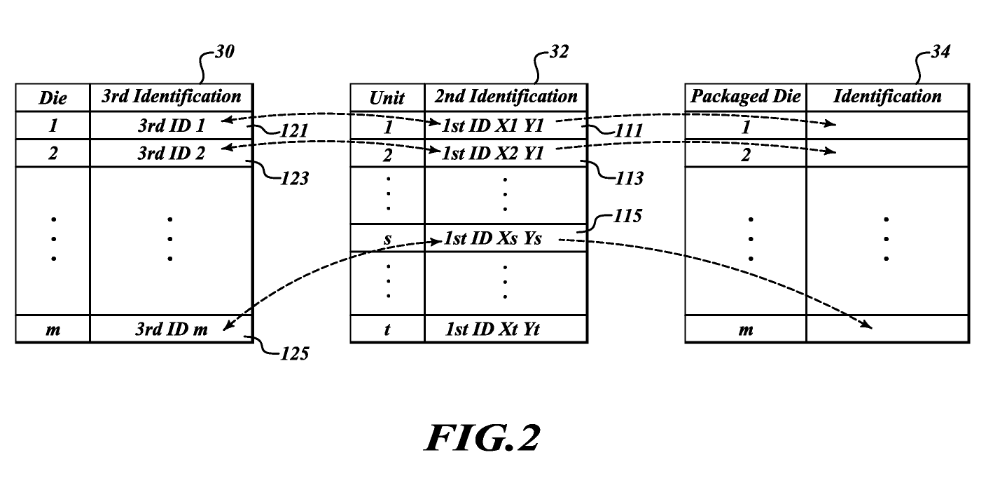

FIG. 2 illustrates schematically the mapping method between the various identifications of the support member 18, the die support unit 20, and the wafer map. In FIG. 2, the wafer map identification is represented by a schematic block 30. In one embodiment, the wafer map identification data includes two pieces of information: the wafer identification and the die coordinate on that particular wafer 12. Die support unit tracking is represented by block 32 in which the specific coordinate of a particular die support until on the larger support member 18 is identified.

Referring back to FIG. 1, while viewing FIG. 2, a particular die 16 from each of the respective wafers 12 is placed on the respective die support units 111, 113 and 115. As shown in FIG. 1, a die 121 from a first wafer 12 is placed on die support until 111 on the support member 18. Similarly, a die 123 is placed on the adjacent die support member 113 on the same support member 18 as the previous die. In this instance, the dies 121 and 123 came from different wafers and yet are positioned side-by-side on the same die support member 18. This could be common in the industry, particularly when a bin sort is carried out and dies 121 and 123 are determined to be in the same bin, even though they came from separate wafers or even from separate lots. Similarly, a die 125 from a separate wafer 12 is placed on die support unit 115 of the same support member 18. As illustrated in FIG. 2, the X and Y coordinate of each individual die on the support member 18 is tracked according to the location of the particular die support unit.

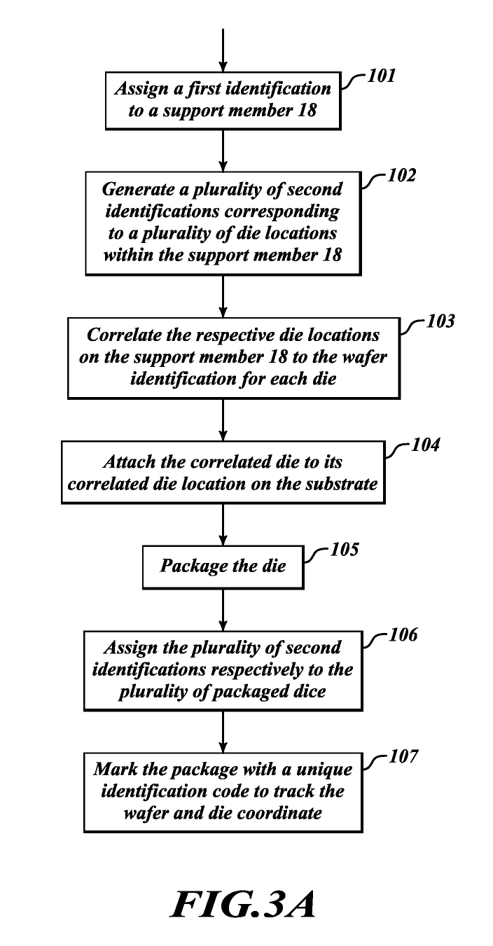

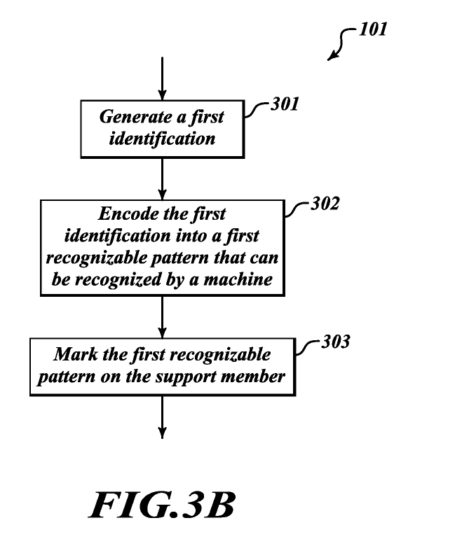

The marking of the completed package with an indication on the outside of the package of the die coordinate and wafer identification is represented in block 34. It is known today that the outside of the package is marked with an identification of the type of die in the package, for example, whether it is a microprocessor or memory, and also other features such as the particular model number of the die and the speed of die. According to embodiments of the present invention, the outside of the package is also marked with an indication that provides sufficient information to know the wafer identification and the die coordinate on that wafer that would permit a person viewing the package to locate and obtain the wafer map for that particular wafer and for that particular die. How this is done will now be explained with respect to the flow chart of FIG. 3A and the remaining Figures.

Hereinafter, the flow chart of the method of tracing dice shown in FIG. 3A will be elaborated by also referring to FIGS. 1 and 2.

In step 101, a first identification is assigned to a support member 18. As shown in FIG. 2, the support member 18 includes a plurality of die support units 20, for example, individual die support units 111, 113 and 115.

In step 102, a plurality of second identifications are generated at table 32 corresponding to each respective die support unit within the support member 18. Each of the second identifications includes the a identification and a coordinate of the corresponding die support unit within the support member 11. In this instance, the first identification is the identification of the particular substrate member 18 to which the individual die unit belongs. As explained in more detail later herein, each substrate member 18 is assigned a tracking identification number which serves to provide an identification of the particular support member 18 to which the individual dies 16 are being attached. This is indicated with the words “first ID” as shown in block 32 of FIG. 2. The second identification number provides the X and Y coordinates of the particular die support unit 20 on the support member 18. For example, the second identification corresponding to the die support unit 111 includes the first identification and the coordinate of the die support unit 111 within the support member 18. The second identification corresponding to the die support unit 113 includes the first identification and the coordinate of the die support unit 113 within the support member 11. And the second identification 15 corresponding to the die support unit 115 includes the first identification and the coordinate of the die support unit 115 within the support member 11.

The table 32 also stores the correspondence between the die placed on a particular die support unit 20 and the wafer coordinate information from table 30 of the particular die. As can be seen in FIG. 2, the information that die 121 is placed at coordinate X1, Y1 is stored with respect to table 32 and that die 123 is stored at die support unit X2, Y1 is also stored.

In step 103, the plurality of second identifications 15 are correlated in one-to-one correspondence to a plurality of third identifications 17 of dice 12.

In step 104, the dice 12 are respectively attached to the plurality of die support units to be ready to assemble the packaged dice 13. To be specific, the dice 12 are picked from the wafer and respectively attached to the plurality of die support units and then packaged to be a plurality of packaged dice 13.

In some embodiments, the wafer identification is correlated with a wafer map. In one embodiment, the wafer map is generated for a tested wafer and stores characterizations of the plurality of dice within the correlated wafer, for example, bin codes, test parameters, etc.

It will be appreciated that the plurality of third identifications 17 are different from each other. In one embodiment, each of the third identifications 17 includes a die coordinate and a corresponding wafer identification, and thus each die from a single wafer or a plurality of wafers has a unique identification. In an alternative embodiment, each of the third identifications 17 further includes other die-related information, for example a corresponding wafer lot identification.

The die are then packaged in step 105, such as by encapsulation, applying a molding compound, attaching to a ball grid array, a land grid array, or the like

In step 106, the plurality of second identifications 15 are assigned respectively to the plurality of packaged dice 13.

In step 107, the packaged die are mounted with a unique identification which, if read by someone who knows the correct codes, will identify the wafer and die coordinate on the wafer.

The method for tracing die according to one embodiment of the present invention, as schematically shown in FIG. 1, may be successfully applied to different systems. For example, in one embodiment, the method is applied to lead frame packaging and the support member 11 is a lead frame. In an alternative embodiment, the method is applied to ball grid array (BGA) packaging and the support member 11 is a BGA support member and can be made of bismaleimide and triazine (BT) resin, ceramic, metal or other suitable material.

FIG. 3B is an example flowchart of the step 101 according to the embodiment illustrated in FIGS. 1 and 2.

In step 301, a first identification is generated for the support member.

It will be appreciated that the step 301 can be implemented with a storage medium storing a computer readable program enabling generation of a first identification for the support member 11. In one embodiment, the first identification contains information related to the support member 11, such as product code, code of marking equipment and running series number. An example of the first identification is shown below:

1S09061400000001

Wherein “1” in the first digit denotes the product code of the support member 18, “S” in the second digit denotes equipment code of the marking equipment which marks the first recognizable pattern on the support member 18, the numbers “090614” in the following digits denote the year, month and date when the support member 18 is marked with the first recognizable pattern, and “00000001” in the last eight digits denotes the running series number generated for the support member 18. The running series number is generated so that the support member 18 can be differentiated from other support members.

Then, in step 302, the first identification is encoded into a first recognizable pattern that can be recognized by a machine.

It will be appreciated that one-dimensional array or two-dimensional matrix format or other applicable formats can be utilized in the encoding process.

Preferably two-dimensional matrix format is utilized to achieve the first recognizable pattern that is capable of carrying more information related to the support member 18 while occupying less space.

In step 303, the first recognizable pattern is marked on the support member 18. The first recognizable pattern may be marked on the support member 18 for different purposes, for example, product tracking.

It will be appreciated that the first recognizable pattern can be marked with various methods, such as ink-jet, dot-peen marking, laser marking, electrolytic chemical etching (ECE) and other suitable methods.

It should be appreciated that the first recognizable pattern may be marked directly on the support member 18 and may be marked on anywhere outside the device region of the support member 18, for example, the sidewall portion or the edge portion of the surface.

It should be further appreciated that multiple first recognizable patterns can be marked on the support member 18 so that the support member 18 can still be identified in case some of the first recognizable patterns are damaged.

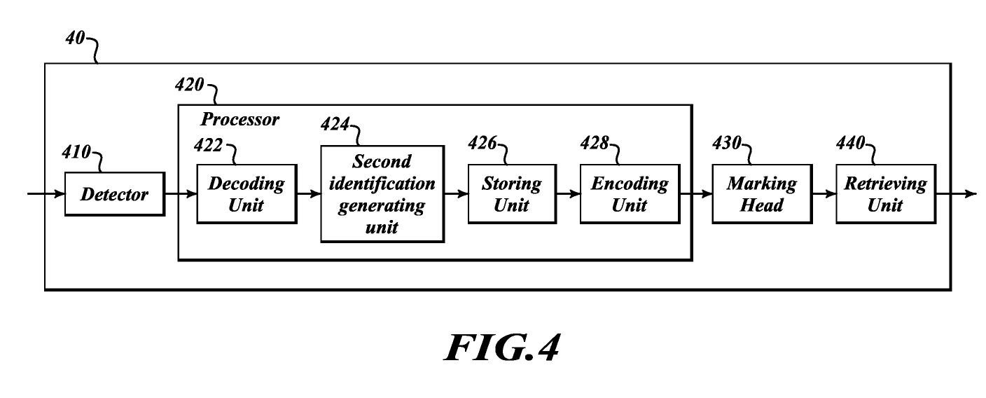

FIG. 4 illustrates a schematic view of a system 40 that can implement the steps 102-107 according to the embodiment illustrated in FIGS. 1-3B. The system 40 comprises a detector 410; a processor 420 including a decoding unit 422, a second identification generating unit 424, a storing unit 426, and an encoding unit 428; a marking head 430; and a retrieving unit 440. Hereinafter, referring to FIGS. 5-7, the steps in FIGS. 1-3B are elaborated accompanying with the system 40.

FIG. 5 illustrates an example flowchart of the step 102 according to the embodiment illustrated in the prior figures.

In step 501, the detector 410 detects the first recognizable pattern from the support member 18.

It will be appreciated that the detector 410 can have various recognition mechanisms. For example, in one embodiment, the detector 410 operates by optical recognition capable of recognizing the first recognizable pattern with parts of different refractive index. In an alternative embodiment, the detector 410 operates by touch-sensing recognition capable of recognizing the first recognizable pattern represented by scribed or trenched surfaces.

In step 502, the decoding unit 422 of the processor 420 decodes the first recognizable pattern into the first identification. In one embodiment, the decoding process of step 502 may be a reverse operation of the encoding one of step 302 as shown in FIG. 3B.

It will be appreciated that the decoding unit 422 can be further configured to convert the first identification into a computer readable format, for example, ASCII.

In step 503, the second identification generating unit 424 of the processor 420 generates a plurality of second identifications 32 corresponding to a plurality of die support units 20, for example die support unit 111, 113 and 115 as shown in FIG. 1 within the support member 18 on the basis of the first identification. Each of the second identifications 15 includes the first identification and the coordinate, for example, the row and column position, of the corresponding die support unit 20 on the particular support member 18. Thus each of the die support units has a unique identification. An example of table 32 is shown in table 1 below for of the second identifications is shown below:

TABLE 1

| First | Coordi- | Coordi- | Second |
|---|---|---|---|
| identification | nate X | nate Y | identification |
| 1S09061400000001 | 01 | 1 | 1S09061400000001011 |
| | 02 | 1 | 1S09061400000001021 |
| | . . . | . . . | . . . |
| | 13 | 2 | 1S09061400000001132 |

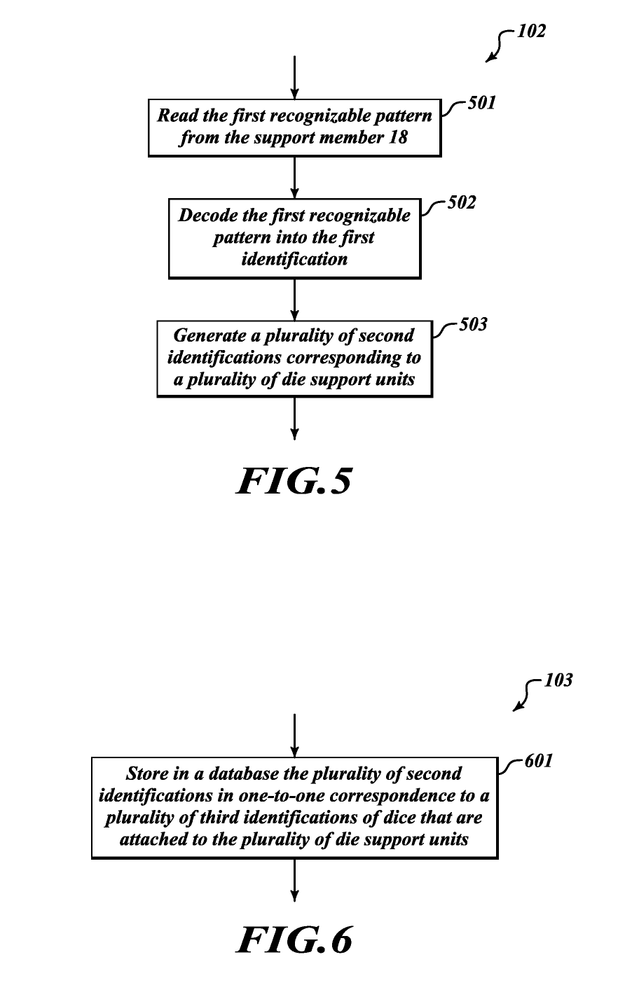

FIG. 6 illustrates an example flowchart of the step 103 according to the embodiment illustrated in the prior figures.

In step 601, the storing unit 426 of the processor 420 stores in a database the plurality of second identifications 32 in one-to-one correspondence to a plurality of third identifications 30 of dice 16 that are attached to the plurality of die support units and then packaged to be a plurality of packaged dice 22 (see FIGS. 1 and 2).

For example, the storing unit 426 may add a field to a table 30 or 32 stored in the database, the table containing the plurality of third identifications of dice 16, and may write in the table the plurality of second identifications in one-to-one correspondence to the plurality of third identifications.

In this way, a link between the front-end process and the back-end process is established.

It should be appreciated that in the case of a stacked die package, one second identification may correspond to a plurality of third identifications of dice 16 which are stacked on the die support unit 20.

It should be further appreciated that the plurality of dice 16 attached to the plurality of die support units 20 can be singulated dice from a single wafer 12 or different wafers in a same lot or different wafers from different lots.

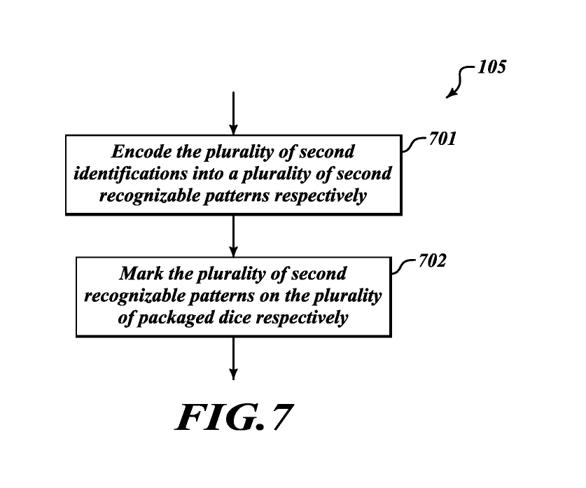

FIG. 7 illustrates an example flowchart of step 107 according to the embodiment illustrated in the prior figures.

In step 701, the encoding unit 428 of the processor 420 encodes the plurality of second identifications 15 into a plurality of second recognizable patterns respectively.

It will be appreciated that the encoding unit 428 can utilize one-dimensional array or two-dimensional matrix format or other applicable formats in the encoding process. Preferably two-dimensional matrix format is utilized to achieve the first recognizable pattern that is capable of carrying more information related to the support member 18 while occupying less space.

In step 702, the marking head 430 marks the plurality of second recognizable patterns on the plurality of packaged dice 13 respectively. The second recognizable pattern may be marked on the plurality of packaged dice 22 for a plurality of purposes, for example, product tracking.

It will be appreciated that the marking head 430 can mark the plurality of second recognizable patterns on the plurality of packaged dice 13 with various methods, such as ink-jet, dot-peen marking, laser marking, electrolytic chemical etching (ECE) and other suitable methods.

In another embodiment, the method of tracing die shown in FIG. 1 further comprises the step of: on the basis of the second identification of a target packaged die that is selected from the plurality of packaged dice 22, tracing at least one of: a correlated third identification of a die, and one or a plurality of packaged dice with second identifications which include the same first identification as that included in the second identification of the target packaged die.

The above step can be achieved by the system 40 through, for example, the retrieving unit 440.

To be specific, the detector 410 comprised in the system 40 further detects the second recognizable pattern from the target packaged die that is selected from the plurality of packaged dice 13, and the decoding unit 422 of the processor 420 decodes the second recognizable pattern into a second identification of the target packaged die.

Then, the retrieving unit 440 retrieves from the database at least one of: the third identification, and the information of one or a plurality of packaged dice with second identifications which include the same first identification as that included in the second identification of the target packaged die.

Table 2 and 3 illustrate example identification mapping records retrieved from the database according to one embodiment of the present invention.

As shown in table 2, the information related to the target packaged die can be achieved from the records, such as the wafer lot number, the wafer identification and the coordinates of the die on the sawed wafer. Since each tested wafer has a correlated wafer map, the historical information and characterizations of the target packaged, such as which lot the die belong to, the manufacturing steps undergone and the electrical testing results at respective stages, can be achieved. These information and characterizations would be helpful to track down the problem if the packaged die is later found unreliable.

TABLE 2

| Second | Wafer | Wafer | Die | First | Die support unit |
|---|---|---|---|---|---|
| identification | Lot | No. | Coordinates | identification | coordinates |
| 1S09061400000001011 | V2345 | 03 | 002, 005 | 1S09061400000001 | 01, 1 |

In addition, as shown in table 3, the information of packaged dice 22 with second identifications which include the same first identification as that included in the second identification of the target packaged die can also be achieved from the records. It would be cost saving and efficient in the way that only affected or related dice, instead of the whole batch, are scraped in case of some dice proved unreliable.

TABLE 3

| Second | Wafer | Wafer | Die | First | Die support unit |
|---|---|---|---|---|---|
| identification | Lot | No. | Coordinates | identification | coordinates |
| 1S09061400000001011 | V2345 | 03 | 002, 005 | 1S09061400000001 | 01, 1 |
| 1S09061400000001021 | V2345 | 03 | 135, 016 | 1S09061400000001 | 02, 1 |
| 1S09061400000001132 | V2346 | 09 | 002, 005 | 1S09061400000001 | 13, 2 |

One embodiment of the present invention also relates to a packaged die 22. The packaged die 22 comprises a die support unit 20 that is separated from a support member 18 including a plurality of die support units 20. The support member 18 is marked with a first recognizable pattern encoded from a first identification. The packaged die further comprises a die that is attached to the die support unit and then packaged to be the packaged die. The die is separated from a wafer that includes a plurality of dice and it has a third identification.

As previously discussed, the support member 18 may be an insulated support for a ball grid array, a printed circuit board holding a flip chip, or other type of packaging. In one embodiment, the support member 18 is temporarily provided as a carrier on which the die 16 are place while the formation of various redistribution layers and encapsulation layers are carried out on the die. Thereafter, the support member 18 is removed from the encapsulated die and discarded or reused. The die are then singulated from each other by sawing the encapsulated material from each other. Thus, in some embodiments, the support member does not travel with the packaged die 22 after the packaging is completed.

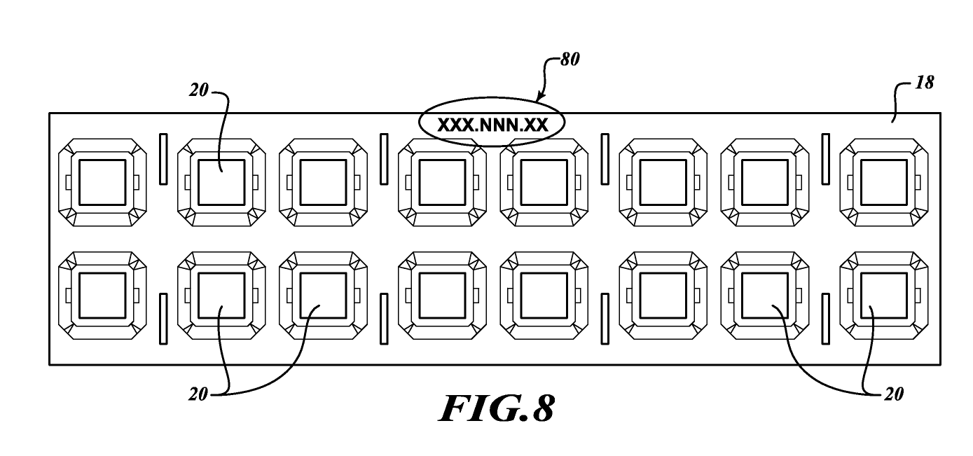

FIGS. 8-10 are provided to illustrate one actual embodiment for carrying out the present invention. FIG. 8 illustrates a support member 18 in the form of a lead frame. This is a standard lead frame of the type well known in the art which includes a large metal strip with a number of electrically connected die pads thereon. The die pads represent the die support units 20 of the support member 18. In the example shown, there are 16 die support units 20 on a single support member 18. In most embodiments, a single support member may include many dozens, or many hundreds, of die support units 20 to which a die 16 may be attached.

As previously explained with respect to FIG. 4, a unique identification code 80 is generated for tracking the support member 18. This unique identification code 80 is placed directly on the lead frame by an appropriate marking mechanism, such as stamping, ink jet printing, laser marking, or the like. In the code 80 shown, the identification stamped on the lead frame is indicated as XXX.NNN.XXX, indicating that the identification code stamped on the lead frame may be a combination of numbers and letters. In addition, it may be a two-dimensional pattern in the form of an array stamped in a location for easy machine reading and easy identification at a subsequent stage in the process.

After the second identification number 80 is clearly marked on the support member 18, it is positioned to receive the individual die 16.

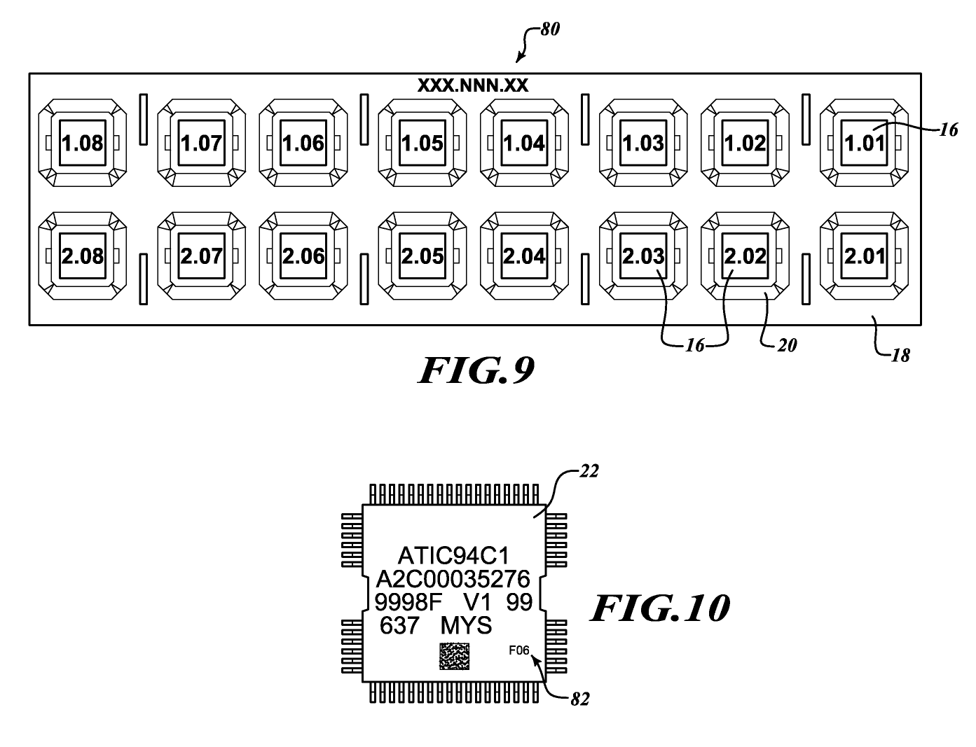

As shown in FIG. 9, a plurality of individual die 16 have been mounted on the downset die pads in each of the lead frames that are the die support units 20. As explained with respect to the previous figures, each of the locations on the support member 18 are identified with a unique coordinate. In the example shown, there are two rows and eight columns. Accordingly, the first row, labeled 1, is identified with the code 1-X, X being the numerical identity of the column. The second row is identified with 2-X. This is one of the techniques by which the particular coordinates of the die 16 which is placed on a particular die support unit 20 can be properly tracked. As previously explained herein, the processor creates a correlation between the location of the particular die 16 on the support member 18 and the wafer map which was previously provided.

The support member 18 is then transported to a location for packaging of the die. In the example in which the support member 18 is a lead frame, the entire lead frame is placed in a mold cavity and liquid molding compound, such as an epoxy or a polymer resin, is flowed into the mold to completely encapsulate each of the die. The molding compound is thereafter cured and the support member 18 removed from the mold. At this time, the die 16 are now packaged in individual packages 22, however, they have not yet marked nor have they been singulated with respect to each other. The marking head thereafter prepares to place the appropriate identification upon each of the individual package die 22.

The marking head as shown in FIG. 4 has stored therein the information relating to the type of die which has been encapsulated in the respective packages. As the support member 18 approaches the marking head, the detector 410 detects the identity of the code 80 which has been previously applied to the support member 18. The code 80 provides the identification of the particular support member 18 and a link to the tables stored in the memory which permit the system to identify the particular die 16 at each of the coordinate locations on the support member 18. The processor 420 also has been provided an indication of the identity of the wafer and die coordinates on the wafer. These are correlated and matched to the particular die location on the support member 18 that has been packaged and is about to be marked. Of course, it is not necessary to mark the die coordinates locations on the support member 18 or the die support units 20; the computer tracks these based on their physical location as read by the detector 410 or some other detector.

FIG. 10 shows a completely marked, singulated package from the lead frame of FIG. 9 ready for shipment to a customer. As is known in the art, the marking head will mark on the packaged die 22 an indication of the type of die that has been packaged including, in some instances, the packaging date, the chip speed, the chip model number, and other features. In the prior art, the marking has previously indicated date on which the chip was packaged on the outside of the package. However, it has not provided an indication of the date on which the die was actually manufactured nor a possible indication of the wafer from which the die was obtained.

According to the invention, as the marking head is placing the marking identification on the package 22, it also marks a unique identification code 82 onto the package. In the example of FIG. 10, this unique identification code is a three-bit code including a combination of letters and numbers. In the example shown in FIG. 10, the code is “F06.” This code 82, together with the other information of the type of die in the package as printed on the other letters, provides an indication of the particular wafer on which the die was located when it was manufactured and also the coordinates of the die on the wafer, according to one embodiment. Of course, the manufacturer has stored the tables which provide the particular code 82 which, when combined with the other marking indicia on the face of the package, will provide sufficient information to track the wafer number and the die coordinates on that particular wafer. There may also be sufficient information to identify the particular lot from which the wafer was manufactured. Once the wafer identification is known, then by simply looking up an additional stored table, the exact date on which the wafer was manufactured can be known. In addition, the wafer map can be retrieved from the computer storage at which it has been kept by the manufacturer of the wafer. The wafer map will provide an exact identification of the start date for the wafer in the front end process, each of the process steps that the wafer passed through and, since the particular die on the wafer is identified by the code 82, the wafer map will also provide the results of each of the probe tests which were carried out on the die during the manufacturing and wafer probe steps.

The customer of the packaged chip can therefore, at any time, such as the date of purchase, the date of installation, or on a date of chip failure, provide the marked codes on the package and be linked to the die wafer map and, thus, specific details about the wafer manufacture and testing process without having to open the package.

As has been explained, the packaged die 22 is marked with a second recognizable pattern 82 encoded from a second identification that includes the first identification and the coordinate of the die support unit 20, and the second identification is correlated with the third identification.

It will also be readily understood by those skilled in the art that materials and methods may be varied while remaining within the scope of the present invention. It is also appreciated that the present invention provides many applicable inventive concepts other than the specific contexts used to illustrate embodiments. Accordingly, the appended claims are intended to include within their scope such processes, machines, manufacturing, compositions of matter, means, methods, or steps.

The various embodiments described above can be combined to provide further embodiments. All of the U.S. patents, U.S. patent application publications, U.S. patent application, foreign patents, foreign patent application and non-patent publications referred to in this specification and/or listed in the Application Data Sheet are incorporated herein by reference, in their entirety. Aspects of the embodiments can be modified, if necessary to employ concepts of the various patents, application and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method comprising:
receiving an identification of a die that is coupled to a support member;
generating die coordinate location data indicating a location of the disc on the support member;
storing the die identification in a memory;
reading a support member identification from the support member;
storing the support member identification in a memory;
correlating the die identification with the die coordinate location on the support member;
encapsulating the die in a package; and
marking a unique identification code onto the package that indicates a specific die identification.

2. The method according to claim 1 wherein the support member is a metal lead frame for supporting a plurality of die.

3. The method according to claim 1 wherein the support member is a printed circuit board for receiving a ball grid array mounted die.

4. The method of claim 1 wherein said step of receiving an identification of a die includes:
receiving an identification of a wafer of which the die is part;
identifying the location of the die within the wafer;
storing the wafer identification and location of the die within that wafer; and
transmitting the stored information to a location at which the die is to be placed in a package.

5. The method of claim 4 wherein identifying the location of the die on the wafer includes identify an X and Y coordinate location of each die on the wafer.

6. The method of claim 1, further including marking a support member identification onto the support member to which the die is coupled.

7. The method according to claim 1, further including marking a unique identification number on the support member.

8. A method, comprising:
assigning a first identification to a support member having a plurality of dice coupled thereto;
receiving a second identification identifying each die on the support member, the second identification including the first identification and a coordinate of the respective dice within the wafer on which they were manufactured;
correlating the second identification to a wafer identification of a die;
attaching the die to a die support unit to package the die; and
assigning a unique identification to the packaged die.

9. The method of claim 8, further comprising:
on the basis of the second identification of the packaged die, tracing at least one of:
the correlated wafer identification of the die; and
one or a plurality of packaged dice with second identifications which include the same first identification as that included in the second identification of the packaged die.

10. The method of claim 8 wherein the wafer identification includes a die coordinate and a wafer identification correlated with a wafer map.

11. The method of claim 10 wherein the wafer map stores characterizations of a plurality of dice.

12. The method of claim wherein the support member is a metal lead frame.

13. The method of claim 8, wherein the first identification assigning comprises:
generating the first identification;
encoding the first identification into a first recognizable pattern; and
marking the first recognizable pattern on the support member.

14. The method of claim 13, wherein the generating comprises:
detecting the first recognizable pattern from the support member;
decoding the first recognizable pattern into the first identification; and
generating the second identification corresponding to the die support unit on the basis of the first identification, the second identification including the first identification and the coordinate of the die support unit within the support member.

15. The method of claim 8 wherein the correlating comprises:
storing in a database the second identification in one-to-one correspondence to the wafer identification of the die attached to the die support unit.

16. The method of claim 15 comprising:
encoding the second identification into a second recognizable pattern; and
marking the second recognizable pattern on the packaged die.

17. The method of claim 16, further comprising:
detecting the second recognizable pattern from the packaged die;
decoding the second recognizable pattern into the second identification of the packaged die; and
on the basis of the second identification of the packaged die, retrieving from the database at least one of: the wafer identification, and information of one or a plurality of packaged dice with die identifications which include the same first identification as that included in the die identification of the packaged die.

18. A system, comprising:
a detector configured to detect a first recognizable pattern from a support member including a plurality of die support units;
a processor comprising:
a decoding unit configured to decode the first recognizable pattern into a first identification;
an identification generating unit coupled to receive the first identification of the support member from the decoding unit and configured to generate a second identification corresponding to a die support unit within the support member on the basis of the first identification wherein the second identification includes the first identification and the coordinate of the die support unit;
a storing unit configured to store in a database the second identification in one-to-one correspondence to a third identification, the third identification identifying the die that is attached to the die support unit and then packaged; and
an encoding unit configured to encode the second identification into a second recognizable pattern; and
a marking head configured to mark the second recognizable pattern on the packaged die.

19. The system of claim 18, further comprising a retrieving unit, wherein
the detector is further configured to detect the second recognizable pattern from the packaged die;
the decoding unit of the processor is further configured to decode the second recognizable pattern into a second identification of the packaged die; and
the retrieving unit is configured to, on the basis of the second identification of the packaged die, retrieve from the database at least one of: the third identification, and information of one or a plurality of packaged dice with second identifications which include the same first identification as that included in the second identification of the packaged die.

20. The system of claim 18 wherein the third identification includes a die coordinate and a wafer identification correlated with a wafer map.

21. The system of claim 20 wherein the wafer map stores characterizations of a plurality of dice.

22. A packaged die comprising:
a die support unit separated from a support member that includes a plurality of die support units, the support member being marked with a first recognizable pattern encoded from a first identification; and
a die attached to the die support unit and then packaged to be the packaged die, the die being separated from a wafer that includes a plurality of dice and having a third identification,
wherein the packaged die is marked with a second recognizable pattern encoded from a second identification that includes the first identification and the coordinate of the die support unit, and the second identification is correlated with the third identification.
